(19) United States
(12) Patent Application Publication
(10) Pub. No.: US 2017/0229162 A1
(43) Pub. Date: Aug. 10, 2017

(54) NONVOLATILE RAM

(71) Applicant: Kabushiki Kaisha Toshiba, Minato-ku (JP)

(72) Inventors: Hiroki NOGUCHI, Yokohama (JP); Shinobu FUJITA, Tokyo (JP)

(73) Assignee: Kabushiki Kaisha Toshiba, Minato-ku (JP)

(21) Appl. No.: 15/266,393

(22) Filed: Sep. 15, 2016

(30) Foreign Application Priority Data
Feb. 9, 2016 (JP) 2016-022833

(51) Int. Cl. G11C 11/16

(52) U.S. Cl. CPC G11C 11/1675; G11C 11/1673; G11C 11/1677; G11C 11/1655; G11C 11/1657

(57) ABSTRACT

According to one embodiment, a nonvolatile RAM includes an interface block, a memory cell array block, and a signal line connecting the interface block and the memory cell array block. The interface block comprises a command processing portion. The memory cell array block comprises a memory cell array, an access circuit accessing the memory cell array, a read circuit reading read data from the memory cell array, a write circuit writing write data to the memory cell array, and a write control circuit controlling a read operation using the read circuit and a first write operation using the write circuit following the read operation without changing a selected word line in the memory cell array.

### CROSS-REFERENCE T0 RELATED APPLICATIONS

This application is based upon and claims the benefit of priority from Japanese Patent Application No. 2016-022833, filed Feb. 9, 2016, the entire contents of which are incorporated herein by reference.

### FIELD

Embodiments described herein relate generally to a nonvolatile RAM.

### BACKGROUND

The performance of processors can be improved by, for example, increasing the memory capacity of cache memories. In general, volatile RAMs such as static random access memories (SRAMs) are used as the cache memories. Thus, if the memory capacity of the cache memories is increased, power consumption by systems will increase. Accordingly, the use of nonvolatile RAMs such as magnetic random access memories (MRAMs) instead of volatile RAMs is being considered.

### BRIEF DESCRIPTION OF THE DRAWINGS

FIG. 1 shows an example of a system.

FIG. 2 shows an example of a nonvolatile RAM.

FIG. 3 shows an example of a word line control signal.

FIG. 4A and FIG. 4B show examples of read/write enable signals.

FIG. 5 shows an example of a memory cell array, a bit line driver/decoder, and a read circuit.

FIG. 6 shows an example of a write control circuit.

FIG. 7 shows an example of a write circuit.

FIG. 8 shows an example of the read circuit.

FIG. 9 shows an example of read-modified-write.

FIG. 10 shows an operation waveform in the example of FIG. 9.

FIG. 11 shows an example of write-verified-write.

FIG. 12 shows an operation waveform in the example of FIG. 11.

FIG. 13 shows the nonvolatile RAM as a comparative example.

### DETAILED DESCRIPTION

In general, according to one embodiment, a nonvolatile RAM comprises: an interface block; a memory cell array block; and a signal line connecting the interface block and the memory cell array block. The interface block comprises a command processing portion. The memory cell array block comprises: a memory cell array; an access circuit accessing the memory cell array; a read circuit reading read data from the memory cell array; a write circuit writing write data to the memory cell array; and a write control circuit controlling a read operation using the read circuit and a first write operation using the write circuit following the read operation without changing a selected word line in the memory cell array.

Embodiments will be described hereinafter with reference to the accompanying drawings.

### Embodiment

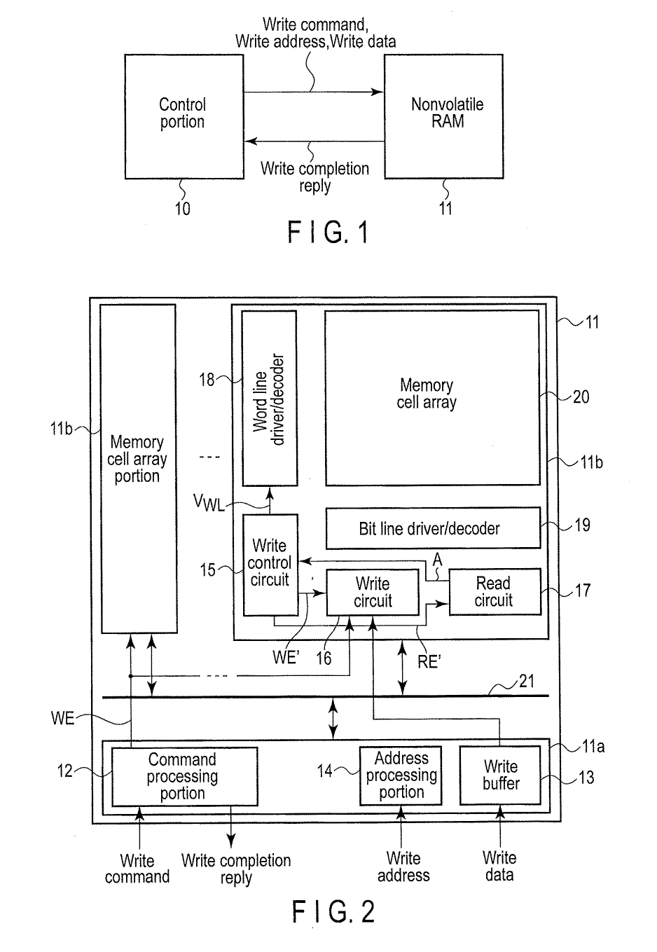

FIG. 1 shows an example of a system.

A system to which the present embodiment is applied comprises a control portion 10 and a nonvolatile RAM 11 controlled by the control portion 10. The control portion 10 is, for example, a host or a controller. The control portion 10 and the nonvolatile RAM 11 may be chips independent of each other, or be included in a single chip such as a processor. The nonvolatile RAM 11 is, for example, an MRAM.

When data is written to the nonvolatile RAM 11, the control portion 10 issues a write command and transfers it to the nonvolatile RAM 11. In addition, the control portion 10 transfers a write address and write data to the nonvolatile RAM 11. The nonvolatile RAM 11, for example, receives a write command, and then transfers a write completion reply to the control portion 10.

In the write to the nonvolatile RAM 11, for example, speeded up writing can be achieved by increasing the write voltage. However, if the write voltage is increased, the rewrite endurance of the nonvolatile RAM 11 deteriorates. That is, there is a trade-off between the speedup in writing and the rewrite endurance.

Under such circumstances, a write to the nonvolatile RAM 11 includes the following characteristic operations. One is a read-modified-write operation intended for speeded up writing, a reduction in power consumption, an improvement in rewrite endurance, etc.

In this operation, upon receipt of a write command, the nonvolatile RAM 11 first reads data of a memory cell of a write address, and verifies whether or not it matches write data. Regarding a bit with both of them matching, a write is omitted. On the other hand, regarding a bit with neither of them matching, a write is executed at a high write voltage. Speeded up writing, a reduction in power consumption, an improvement in rewrite endurance, etc., are thereby attempted.

Another is a write-verified-write operation intended for a reduction in power consumption, an improvement in rewrite endurance, etc.

In this operation, upon receipt of a write command, the nonvolatile RAM 11 executes a write to a memory cell of a write address at a first write voltage, and then executes a read. In addition, it is verified whether or not read data matches write data. Regarding a bit with both of them matching, the write is complete. Regarding a bit with neither of them matching, a write is executed again at a second write voltage greater than the first write voltage. A reduction in power consumption, an improvement in rewrite endurance, etc., are thereby attempted.

Whether to execute a read-modified-write operation or not, or whether to execute a write-verified-write operation or not is determined by the nonvolatile RAM 11 on the basis of information such as the operating temperature of the system, an access pattern, etc. Further, whether to execute these characteristic operations or not may be based on a command from the control portion 10.

Incidentally, the nonvolatile RAM 11, for example, comprises memory cell array portions, and an interface portion common to the memory cell array portions. The interface portion herein refers to an area where a CMOS logic circuit shared by the memory cell array portions is disposed.

The above-described characteristic operations are, for example, controlled by a write control circuit in the interface portion. In this case, read data is transferred from the memory cell array portions to the interface portion via an internal bus (signal line). In addition, the write control circuit in the interface portion compares read data from the memory cell array portions with write data.

Accordingly, because of the transfer of read data, the period for which characteristic operations such as the read-modified-write and the write-verified-write are executed is long. Moreover, the internal bus needs to be driven for the transfer of read data, and power consumption increases.

Thus, the present embodiment proposes a technique of disposing the write control circuit in each of the memory cell array portions. This makes it unnecessary to transfer read data from the memory cell array portions to the interface portion via the internal bus in characteristic operations such as the read-modified-write and the write-verified-write. Thus, speeded up writing to the nonvolatile RAM 11 and a reduction in power consumption can be attempted.

Moreover, in general, the read-modified-write requires two cycles (read→write), and the write-verified-write requires at least three cycles (write read→write). The present embodiment, however, proposes a technique capable of executing them in one cycle. One cycle herein refers to a cycle in which a word line transitions between a low potential (low) and a high potential (high).

That is, the present embodiment also proposes a technique of maintaining a selected state of a selected word line, and for example, continuously executing a read and a write without changing the potential of the selected word line. A swing of the word line can be thereby eliminated, and thus a further reduction in power consumption can be achieved.

(Block Diagram)

FIG. 2 shows an example of a nonvolatile RAM.

The nonvolatile RAM 11 is, for example, an MRAM. The nonvolatile RAM 11 comprises an interface portion 11a and memory cell array portions 11b.

The interface portion 11a, for example, comprises a command processing portion 12, a write buffer 13, and an address processing portion 14.

The memory cell array portions 11b, for example, each comprise a write control circuit 15, a write circuit 16, a read circuit 17, a word line driver/decoder 18, a bit line driver/decoder 19, and a memory cell array 20. The word line driver/decoder 18 and the bit line driver/decoder 19 function as an access circuit which is allowed to access memory cells in the memory cell array 20 at the time of reading/writing.

The command processing portion 12, for example, receives a write command. Upon receipt of the write command, the command processing portion 12 transfers a write enable signal WE to the memory cell array portions 11b.

The write buffer 13 functions as a buffer of write data (input data), and temporarily stores the write data. The write buffer 13 sequentially outputs the write data to the write circuit 16. The address processing portion 14 functions as a buffer of a write address, and sequentially outputs the write address to the word line driver/decoder 18 and the bit line driver/decoder 19.

The write control circuit 15, for example, controls operations characteristic of the nonvolatile RAM 11 such as the read-modified-write and the write-verified-write. For example, the write control circuit 15 outputs a word line control signal V_{WL}, a write enable signal WE′, and a read enable signal RE′ on the basis of the write enable signal WE at the time of writing.

The word line control signal V_{WL} is input to the word line driver/decoder 18. The word line driver/decoder 18 changes the length of one cycle, that is, the period for which a word line is active (for example, at a high potential), on the basis of the word line control signal V_{WL}.

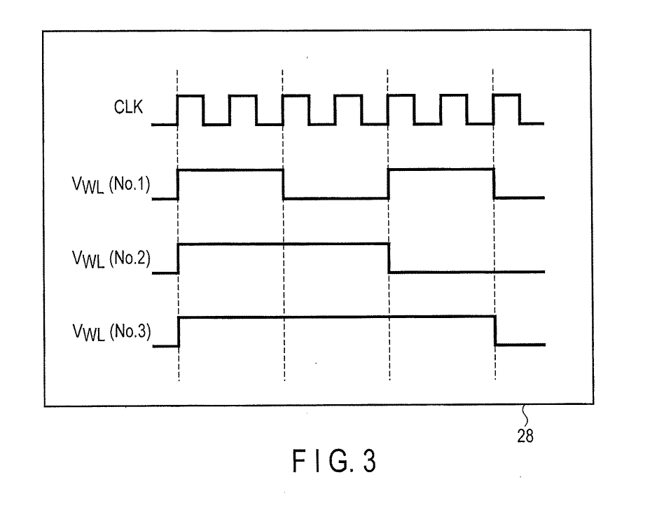

For example, as shown in FIG. 3, the write control circuit 15 is capable of generating three word line control signals V_{WL} (No. 1), V_{WL} (No. 2), and V_{WL} (No. 3) on the basis of a basic clock CLK. The three word line control signals V_{WL} (No. 1), V_{WL} (No. 2), and V_{WL} (No. 3) can be easily generated by using a delay circuit, etc.

In addition, for example, when a normal read is executed, the word line control signal V_{WL} (No. 1) is selected. Moreover, when the read-modified-write is executed in a write, for example, the word line control signal V_{WL} (No. 2) is selected. One cycle of the word line control signal V_{WL} (No. 2) is longer than that of a normal read. Thus, a read and a write in the read-modified-write can be continuously executed without changing a selected word line, for example, without changing the potential of the selected word line.

Moreover, when the write-verified-write is executed in a write, for example, the word line control signal V_{WL} (No. 3) is selected. One cycle of the word line control signal V_{WL} (No. 3) is the longest. Thus, a first write, a read, and a second write in the write-verified-write can be continuously executed while maintaining a selected state of a selected word line, for example, without changing the potential of the selected word line.

The write enable signal WE′ is input to the write circuit 16. The write circuit 16 executes a write to the memory cell array 20 on the basis of the write enable signal WE′. The read enable signal RE′ is input to the read circuit 17. The read circuit 17 executes a read from the memory cell array 20 on the basis of the read enable signal RE′.

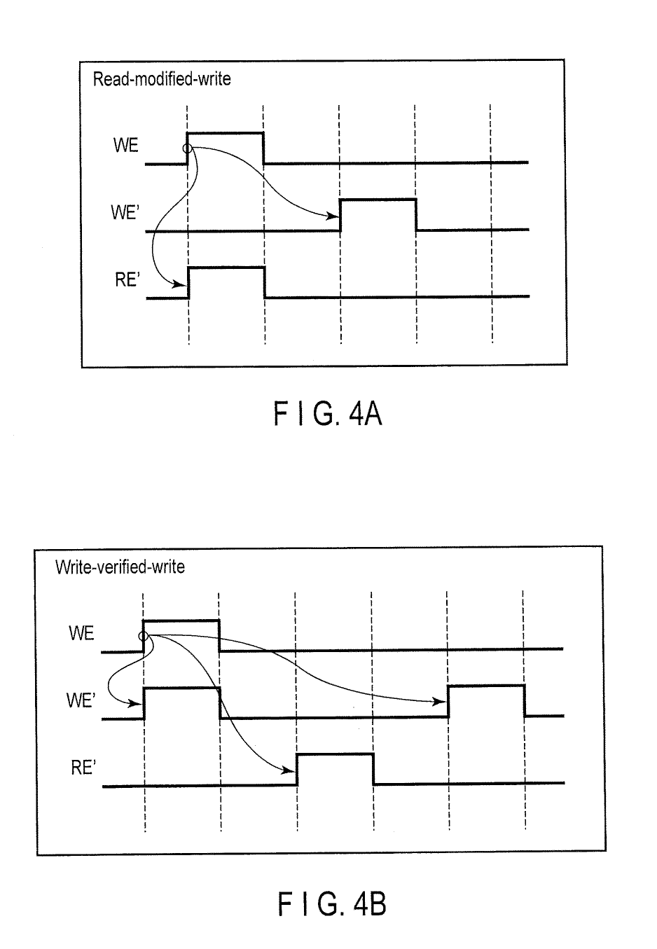

For example, as shown in FIG. 4A, when the read-modified-write is executed in a write, the write control circuit 15 generates the write enable signal WE′ and the read enable signal RE′ on the basis of the write enable signal WE. In addition, as shown in FIG. 4B, when the write-verified-write is executed in a write, the write control circuit 15 generates the write enable signal WE′ and the read enable signal RE′ on the basis of the write enable signal WE.

The write enable signal WE′ and the read enable signal RE′ can be easily generated by using a delay circuit, etc.

In this manner, in the present embodiment, the write control circuit 15 is disposed, not in the interface portion 11a, but in the memory cell array portions 11b. Accordingly, in the characteristic operations such as the read-modified-write and the write-verified-write, read data is not transferred from the memory cell array portions 11b to the interface portion 11a via an internal bus (signal line) 21, but is transferred to the write control circuit 15 in the memory cell array portions 11b (route A).

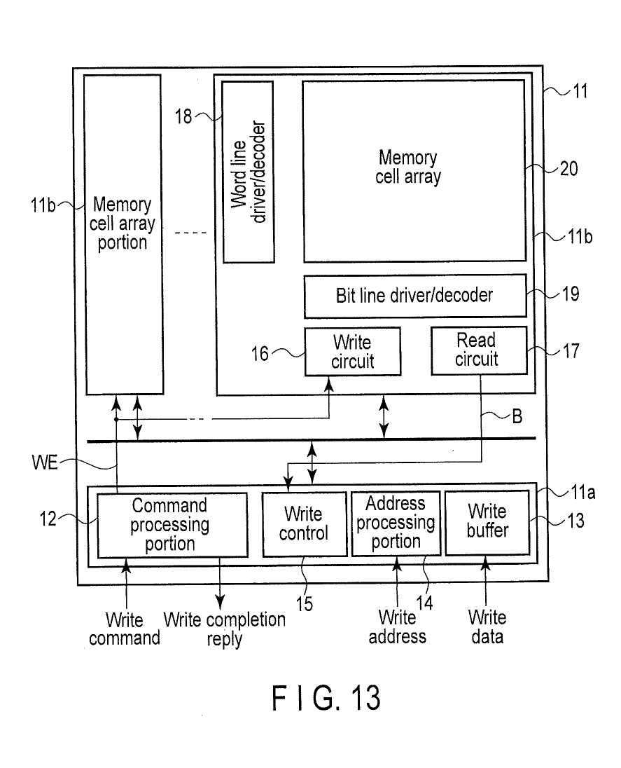

In contrast, for example, in a comparative example shown in FIG. 13, the write control circuit 15 is disposed in the interface portion 11a. In this case, read data is transferred from the memory cell array portions 11b to the interface portion 11a via the internal bus 21 (route B).

Accordingly, in the present embodiment, speeded up writing to the nonvolatile RAM 11 and a reduction in power consumption can be attempted as compared to that in the comparative example.

In addition, since the write control circuit 15 is disposed in the memory cell array portions 11b, the read-modified-write (read→write) and the write-verified-write (write→read→write) can be executed in one cycle. That is, the write control circuit 15 is capable of continuously executing a read and a write while maintaining a selected state of a selected word line in the memory cell array 20, for example, without changing the potential of the selected word line.

Accordingly, a swing of the word line can be eliminated, and thus a further reduction in power consumption can be achieved.

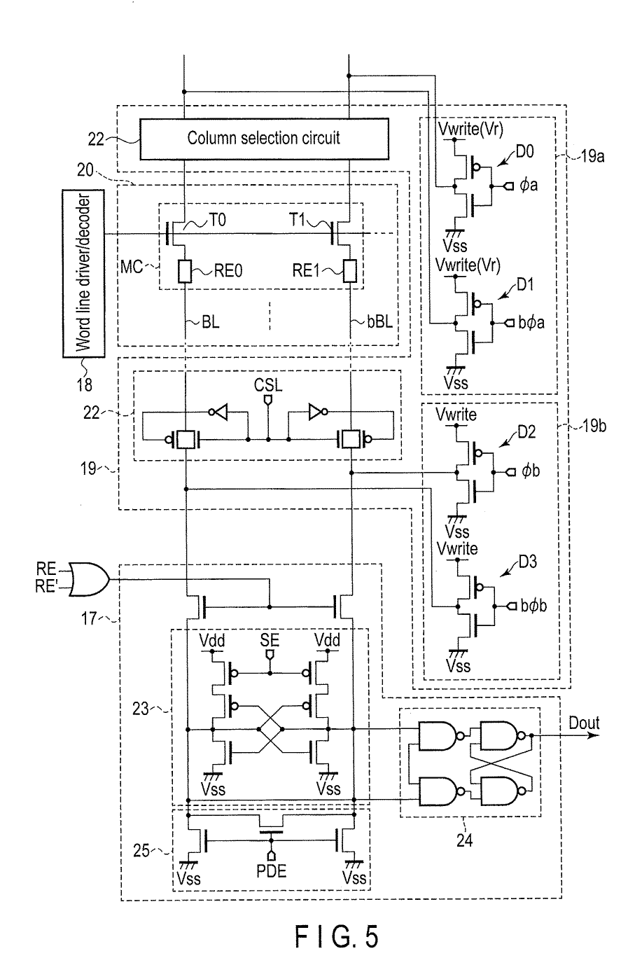

FIG. 5 shows an example of a memory cell array, a bit line driver/decoder, and a read circuit.

The memory cell array 20 includes a memory cell MC. The memory cell MC is a two-cell one-bit type which is capable of storing one bit by two memory elements RE0 and RE1. That is, the memory cell MC comprises a select transistor T0 and the memory element RE0 connected in series, and a select transistor T1 and the memory element RE1 connected in series. The two memory elements RE0 and RE1 store complementary data.

It should be noted that the memory cell MC is not limited to this, and can be variously transformed. For example, the memory cell MC may be a one-cell one-bit type which is capable of storing one bit by the one memory element RE0.

The bit line driver/decoder 19 comprises first and second drivers 19a and 19b and a column selection circuit 22. A decoding circuit in the bit line driver/decoder 19 is omitted. The decoding circuit, for example, decodes a write address and outputs a column selection signal CSL. The column selection signal CSL is input to the column selection circuit 22.

For example, when the column selection signal CSL is active (for example, at a high potential), the memory cell MC is electrically connected to the first and second drivers 19a and 19b or a sense amplifier 23. In addition, when the column selection signal CSL is nonactive (for example, at a low potential), the memory cell MC is electrically disconnected from the first and second drivers 19a and 19b or the sense amplifier 23.

The first driver 19a comprises a driver D0 controlled by a control signal φa and a driver D1 controlled by a control signal bφa. The second driver 19b comprises a driver D2 controlled by a control signal φb and a driver D3 controlled by a control signal bφb.

For example, in a 0-write, the control signal φa is 0, the control signal bφa is 1, the control signal φb is 1, and the control signal bφb is 0. 0 corresponds to, for example, a low potential, and 1 corresponds to, for example, a high potential. The rest is the same as above.

In this case, when a write potential Vwrite as a write pulse is applied, the write pulse is transmitted from the memory element RE0 to the select transistor T0, and from the select transistor T1 to the memory element RE1. Accordingly, for example, the select element RE0 is in a low-resistance state, and the select element RE1 is in a high-resistance state. As a result, 0 is written to the memory cell MC.

In addition, in a 1-write, the control signal φa is 1, the control signal bφa is 0, the control signal φb is 0, and the control signal bφb is 1.

In this case, when a write potential Vwrite as a write pulse is applied, the write pulse is transmitted from the select transistor T0 to the memory element RE0, and from the memory element RE1 to the select transistor T1. Accordingly, for example, the select element RE0 is in a high-resistance state, and the select element RE1 is in a low-resistance state. As a result, 1 is written to the memory cell MC.

In addition, in a read, both of the control signals φa and bφa are 0, and both of the control signals φb and bφb are 1. In this case, when a read potential Vr as a read pulse is applied, the read pulse is transmitted from the select transistor T0 to the memory element RE0, and from the select transistor T1 to the memory element RE1.

At this time, if one of the read enable signals RE and RE′ is active (for example, at a high potential), the sense amplifier 23 senses the potential of a bit line pair BL and bBL. It should be noted that the read enable signal RE is a control signal output by the command processing portion 12 in a normal read, and the read enable signal RE′ is a control signal output by the write control circuit 15 in a write (a read-modified-write operation or a write-verified-write operation).

Read data detected by the sense amplifier 23 is latched in a latch circuit (flip-flop circuit) 24. An output signal Vout of the latch circuit 24 is read data. A bit line equalizing circuit (precharge circuit) 25 is a circuit for setting in advance the bit line pair BL and bBL at a predetermined potential (for example, a ground potential Vss) before a sense operation by the sense amplifier 23. The bit line equalizing circuit 25 sets the bit line pair BL and bBL at the predetermined potential when a control signal PDE is active (for example, at a high potential).

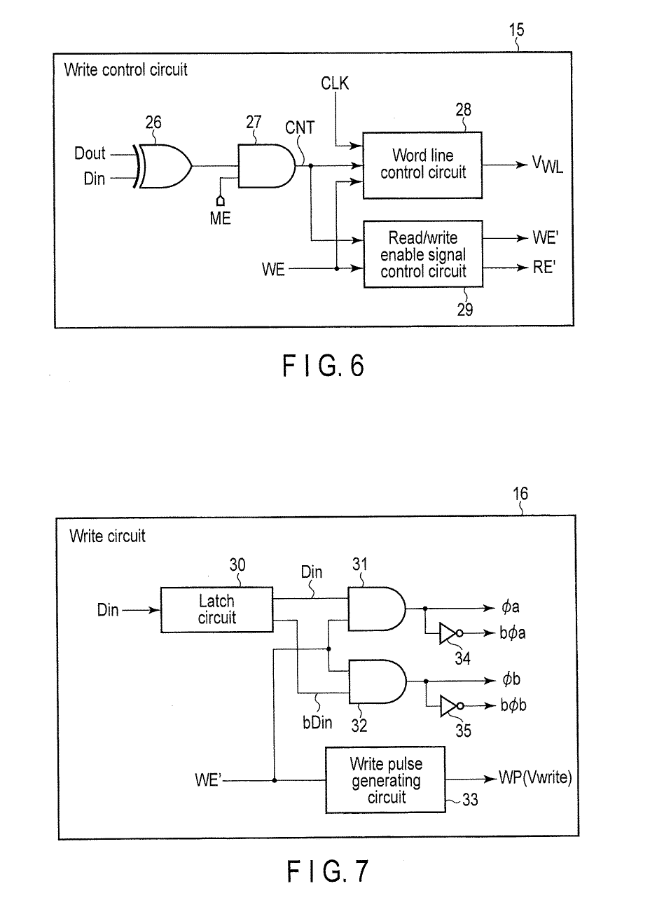

FIG. 6 shows an example of a write control circuit.

The write control circuit 15 comprises an exclusive-OR circuit 26, an AND circuit 27, a word line control circuit 28, a read/write enable signal control circuit 29.

The exclusive-OR circuit 26 functions as a comparison circuit which compares read data Dout and write data Din. If both of them match, the exclusive-OR circuit 26 outputs 0. On the other hand, if neither of them matches, the exclusive-OR circuit 26 outputs 1.

The AND circuit 27 determines whether to continuously execute a read and a write such as the read-modified-write and the write-verified-write or not on the basis of a control signal ME. The control signal ME is, for example, issued by the command processing portion 12 of FIG. 2.

For example, the control portion 10 of FIG. 1 determines whether to execute characteristic operations such as the read-modified-write and the write-verified-write or not on the basis of information such as the operating temperature of the system and an access pattern. If these operations are executed, the control portion 10 of FIG. 1 transfers a predetermined command to the nonvolatile RAM 11 of FIG. 1. Upon receipt of the predetermined command, the command processing portion 12 of FIG. 2 sets the control signal ME active (for example, 1) and transfers it to the write control circuit 15.

When the control signal ME is 1, the AND circuit 27 transfers an output signal of the exclusive-OR circuit 26 as a comparison circuit to the word line control circuit 28 and the read/write enable signal control circuit 29 as it is as a control signal CNT.

When the control signal CNT is active (for example, 1), the word line control circuit 28 outputs the word line control signal V_{WL} on the basis of the basic clock CLK.

For example, if a read-modified-write operation is executed and the read data Dout does not match the write data Din, the control signal CNT is 1. Accordingly, the word line control circuit 28, for example, outputs the word line control signal V_{WL} (No. 2) of FIG. 3. In addition, if a write-verified-write operation is executed and the read data Dout does not match the write data Din, the control signal CNT is 1. Accordingly, the word line control circuit 28, for example, outputs the word line control signal V_{WL} (No. 3) of FIG. 3.

When the control signal CNT is active (for example, 1), the read/write enable signal control circuit 29 outputs the read enable signal RE′ and the write enable signal WE′ on the basis of the write enable signal WE.

For example, if a read-modified-write operation is executed and the read data Dout does not match the write data Din, the control signal CNT is 1. Accordingly, the read/write enable signal control circuit 29, for example, outputs the read enable signal RE′ and the write enable signal WE′ with timing shown in FIG. 4A.

In addition, if a write-verified-write operation is executed and the read data Dout does not match the write data Din, the control signal CNT is 1. Accordingly, the read/write enable signal control circuit 29, for example, outputs the read enable signal RE′ and the write enable signal WE′ with timing shown in FIG. 4B.

If the read data Dout matches the write data Din, an output signal of the exclusive-OR circuit 26 changes from 1 to 0. When the output signal of the exclusive-OR circuit 26 changes to 0, the control signal CNT changes to 0. Accordingly, thereafter, the word line control circuit 28 does not prolong the period for which the potential of a word line is active, and the read/write enable signal control circuit 29 does not newly output the read enable signal RE′ or the write enable signal WE′.

FIG. 7 shows an example of a write circuit.

The write circuit 16 comprises a latch circuit 30, AND circuits 31 and 32, a write pulse generating circuit 33, and inverter circuits 34 and 35.

The latch circuit 30, for example, latches the write data Din while executing characteristic operations such as the read-modified-write and the write-verified-write. The write data Din is input into the AND circuit 31, and inversion data bDin of the write data Din is input to the AND circuit 32. When the write enable signal WE′ is active (for example, 1), the AND circuits 31 and 32 output the control signals φa, bφa, φb, bφb according to the value of the write data Din.

The control signals φa, bφa, φb, bφb are, for example, transferred to the first and second drivers 19a and 19b of FIG. 5 at the time of writing.

When the write enable signal WE′ is active (for example, 1), the write pulse generating circuit 33 outputs a write potential Vwrite as a write pulse WP. The write potential Vwrite as a write pulse WP is, for example, transferred to the first and second drivers 19a and 19b of FIG. 5 at the time of writing.

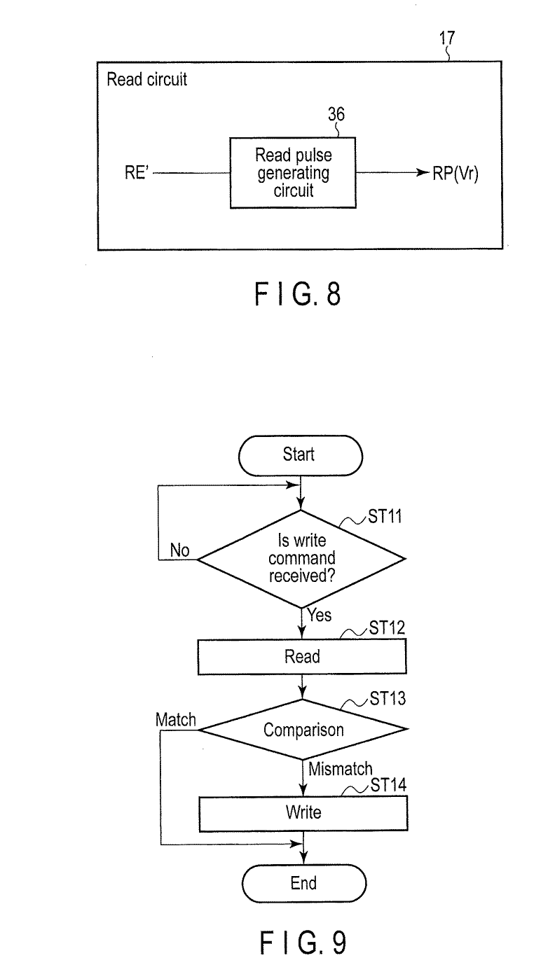

FIG. 8 shows an example of a read circuit.

The read circuit 17 comprises a read pulse generating circuit 36.

When the read enable signal RE′ is active (for example, 1), the read pulse generating circuit 36 outputs a read potential Vr as a read pulse RP. The read potential Vr as a read pulse RP is, for example, transferred to the first driver 19a of FIG. 5 at the time of reading.

The read circuit 17, for example, has the function of setting both of the control signals φa and bφa, transferred to the first and second drivers 19a and 19b of FIG. 5 to 0, and setting both of the control signals φb and bφb to 1, at the time of reading.

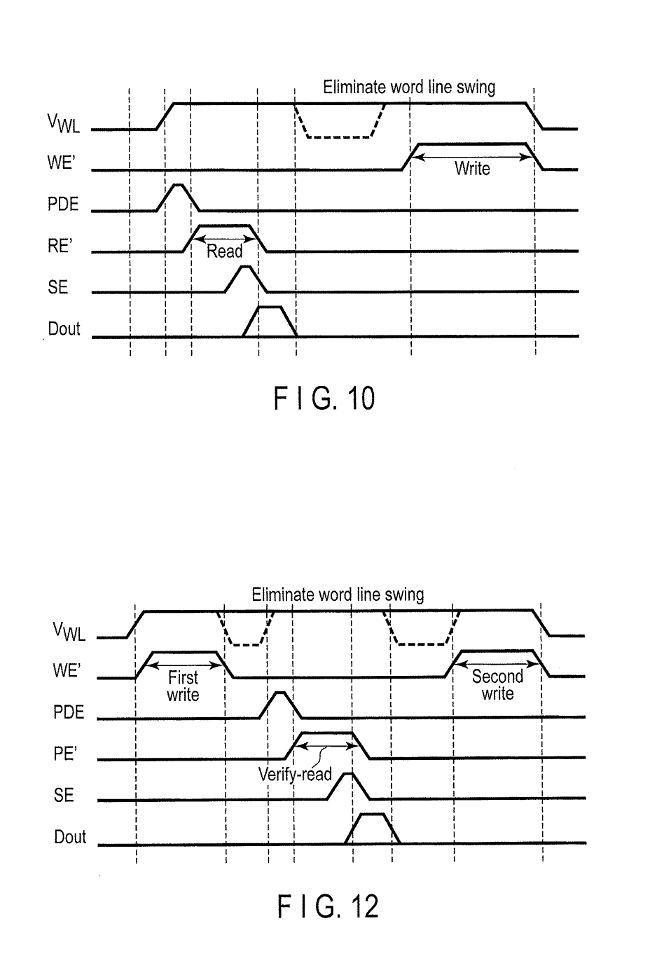

FIG. 9 shows an example of the read-modified-write. FIG. 10 shows an operation waveform in the example of FIG. 9.

In FIG. 10, V_{WL}, WE′, and RE′ correspond to, for example, V_{WL}, WE′, and RE′ of FIG. 6. In addition, PDE, SE, and Dout correspond to PDE, SE, and Dout of FIG. 5.

In a read-modified-write operation, first, if a write command is received, a read is executed (steps ST11 and ST12). Read data and write data are compared, and if both of them match, a write is not executed and is complete. On the other hand, if neither of them matches, a write is executed (steps ST13 and ST14).

The read-modified-write is characterized in that the word line control signal V_{WL} maintains an active state from a read to a write as shown in FIG. 10 (solid line). That is, the word line control signal V_{WL} does not change from the read to the write. This means that the potential of a word line does not substantially change from the read to the write.

Not substantially changing herein means that the word line maintains a high potential from the read to the write when the potential of the word line is at a high potential (high level), and maintains a low potential from the read to the write when it is at a low potential (low level).

Accordingly, a swing of the word line can be eliminated, and thus a further reduction in power consumption can be achieved.

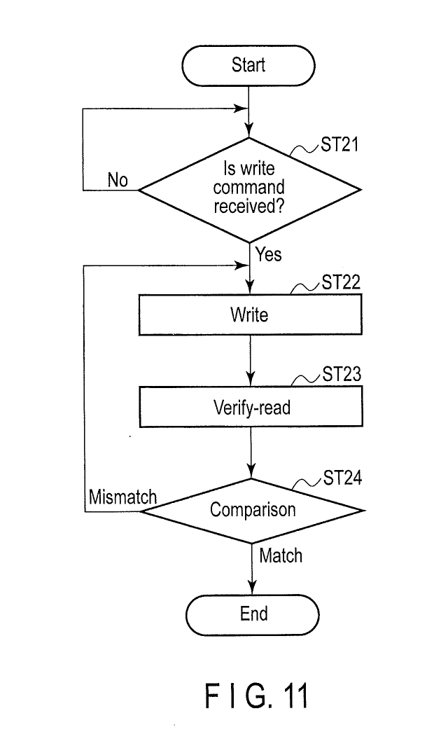

FIG. 11 shows an example of the write-verified-write. FIG. 12 shows an operation waveform in the example of FIG. 11.

In FIG. 12, V_{WL}, WE′, and RE′ correspond to, for example, V_{WL}, WE′, and RE′ of FIG. 6. In addition, PDE, SE, and Dout correspond to PDE, SE, and Dout of FIG. 5.

In a write-verified-write operation, first, if a write command is received, a write is executed (steps ST21 and ST22). Then, a so-called verified-read is executed (step ST23). Read data and write data are compared, and if both of them match, the write is complete. On the other hand, if neither of them matches, a write is executed again (step ST24).

The write-verified-write is characterized in that the word line control signal V_{WL} maintains an active state from a first write to a second write via a read as shown in FIG. 12 (solid line). That is, the word line control signal V_{WL} does not change from the first write to the second write. This means that the potential of a word line does not substantially change from the first write to the second write.

Accordingly, a swing of the word line can be eliminated, and thus a further reduction in power consumption can be achieved.

(Conclusion)

As described above, according to the present embodiment, speeded up writing to the nonvolatile RAM and a further reduction in power consumption can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile RAM comprising:
an interface block; a memory cell array block; and a signal line connecting the interface block and the memory cell array block,
wherein the interface block comprises a command processing portion, and
the memory cell array block comprises:
a memory cell array;
an access circuit accessing the memory cell array;
a read circuit reading read data from the memory cell array;
a write circuit writing write data to the memory cell array; and
a write control circuit controlling a read operation using the read circuit and a first write operation using the write circuit following the read operation without changing a selected word line in the memory cell array.

2. The nonvolatile RAM of claim 1, wherein
the command processing portion outputs a write enable signal on the basis of a write command,
the write control circuit controls the read operation and the first write operation following the read operation on the basis of the write enable signal.

3. The nonvolatile RAM of claim 2, wherein
the first write operation is executed on the basis of a result of the read operation.

4. The nonvolatile RAM of claim 3, wherein
the write control circuit outputs a read enable signal on the basis of the write enable signal, and
the read operation is executed on the basis of the read enable signal.

5. The nonvolatile RAM of claim 3, wherein
the write control circuit controls the read operation and the first write operation following the read operation on the basis of a control signal from the command processing portion.

6. The nonvolatile RAM of claim 3, wherein
the read operation and the first write operation following the read operation are executed without changing a potential of the selected word line.

7. The nonvolatile RAM of claim 3, wherein
the write circuit includes a latch circuit storing the write data.

8. The nonvolatile RAM of claim 7, wherein
the first write operation following the read operation is executed when the read data reading by the read operation is not coincident with the write data stored in the latch circuit.

9. The nonvolatile RAM of claim 7, wherein
the first write operation following the read operation is not executed when the read data reading by the read operation is coincident with the write data stored in the latch circuit.

10. The nonvolatile RAM of claim 2, wherein
the write control circuit controlling a second write operation using the write circuit, and
the write control circuit controls the second write operation, the read operation following the second write operation and the first write operation following the read operation on the basis of the write enable signal.

11. The nonvolatile RAM of claim 10, wherein
the second write operation, the read operation following the second write operation and the first write operation following the read operation are executed without changing the selected word line.

12. The nonvolatile RAM of claim 10, wherein
the first write operation is executed on the basis of a result of the read operation.

13. The nonvolatile RAM of claim 10, wherein
the write control circuit outputs a read enable signal on the basis of the write enable signal, and
the read operation is executed on the basis of the read enable signal.

14. The nonvolatile RAM of claim 10, wherein
the write control circuit controls the second write operation, the read operation following the second write operation and the first write operation following the read operation on the basis of a control signal from the command processing portion.

15. The nonvolatile RAM of claim 10, wherein
the second write operation, the read operation following the second write operation and the first write operation following the read operation are executed without changing a potential of the selected word line.

16. The nonvolatile RAM of claim 10, wherein the write circuit includes a latch circuit storing the write data.

17. The nonvolatile RAM of claim 16, wherein
the first write operation following the read operation is executed when the read data reading by the read operation is not coincident with the write data stored in the latch circuit.

18. The nonvolatile RAM of claim 17, wherein
the read operation is an operation verifying about whether the write data is stored in the memory cell array by the second write operation.

19. The nonvolatile RAM of claim 16, wherein
the first write operation following the read operation is not executed when the read data reading by the read operation is coincident with the write data stored in the latch circuit.

20. The nonvolatile RAM of claim 19, wherein
the read operation is an operation verifying about whether the write data is stored in the memory cell array by the second write operation.
